(19) United States
(12) Patent Application Publication
(10) Pub. No.: US 2009/0034193 A1
(43) Pub. Date: Feb. 5, 2009

(54) HEAT-DISSIPATING MODULE

(75) Inventors: Feng-Ku Wang, Taipei City (TW); Chih-Kai Yang, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 11/851,097

(22) Filed: Sep. 6, 2007

(30) Foreign Application Priority Data
Jul. 30, 2007 (TW) 96127753

(51) Int. Cl. H05K 7/20

(52) U.S. Cl. 361/697

(57) ABSTRACT

A heat-dissipating module adapted for cooling a heat-generating element is provided. The heat-dissipating module includes a plurality of fins, a fan and a heat pipe. The fan is adapted for generating an air current. Each fin has an edge facing the fan. The edges are located on a folded surface. The air current first passes through the folded surface and then passes by the fins. The heat pipe includes a first end thermally coupled to the heat-generating element, and a second end thermally coupled to the fins.

### CROSS-REFERENCE TO RELATED APPLICATION

This application claims the priority benefit of Taiwan application serial no. 96127753, filed on Jul. 30, 2007. All disclosure of the Taiwan application is incorporated herein by reference.

### BACKGROUND OF THE INVENTION

1. Field of the Invention

The present invention relates to a heat-dissipating module, and more particularly, to a heat-dissipating module with fins.

2. Description of Related Art

With rapid advance of computer technology in recent years, computers are made to operate at higher frequency, and a heat generation rate of each of electronic elements in a computer host has become greater and greater. To avoid temporary or permanent failure of the electronic elements in the computer host due to overheat, dissipating the heat generated by the electronic elements in the computer host is of critical importance.

Taking a central processing unit (CPU) as an example, when the temperature of the CPU itself exceeds its normal operating temperature during operation at high frequency, operation errors or temporary failures of the CPU will probably occur, resulting in a crash of the computer host. In addition, when the temperature of the CPU itself is much higher than its normal operating temperature, transistors in the CPU will be probably damaged, resulting in the permanent failure of the CPU.

FIG. 1A is a three-dimensional exploded view of a conventional heat-dissipating module, and FIG. 1B is a three-dimensional assembled view of the heat-dissipating module of FIG. 1A. As shown in FIGS. 1A and 1B, the conventional heat-dissipating module 100 is adapted for cooling a heat-generating element 10. The heat-dissipating module 100 includes a fin module 110, a fan 120, a heat pipe 130, a casing 140 and a heat-conducting element 150. The fin module 110 includes a plurality of fins 114. Each fin 114 has an edge 114a and each edge 114a facing the fan 120 is straight. The edges 114a of the fins 114 are located on a plane 112.

The fan 120 is disposed in an accommodating space 142 of the casing 140 and adjacent to the plane 112. An outlet 144 of the casing 140 corresponds to the plane 112 in such a manner that an air current 122 generated by the fan 120 may flow through the outlet 144 and the plane 112 and then into a clearance 116 formed between each two adjacent fins 114. In addition, the heat pipe 130 includes a first end 132 and a second end 134. The first end 132 is thermally coupled to the heat-generating element 10 through the heat-conducting element 150, and the second end 134 passing through the fins 114 is thermally coupled to the fins 114.

With the development of the computers toward miniaturization, the room for the heat-dissipating module 100 is becoming smaller and smaller. However, a minimum distance between the fan 120 and the plane 112 must be maintained to be larger than a predetermined value, or the turbulence occurring at the plane 112 becomes even worse to increase the noise during operation of the fan 120. Therefore, to meet the requirements of the miniaturization of the heat-dissipating module 100 without increasing the noise, the conventional solution is to reduce the size of the fan 120 or reduce the length of each fin 114. However, any of the above solutions may degrade the heat-dissipating capacity of the heat-dissipating module 100.

### SUMMARY OF THE INVENTION

The present invention is directed to a heat-dissipating module with low noise and good heat-dissipating capacity.

The present invention provides a heat-dissipating module adapted for cooling a heat-generating element. The heat-dissipating module comprises a plurality of fins, a fan and a heat pipe. The fan is adapted for generating an air current. Each of the fins has an edge facing the fan. The edges are located on a folded surface. The air current passes through the folded surface and then passes by the fins. A first end of the heat pipe is thermally coupled to the heat-generating element, and a second end of the heat pipe is thermally coupled to the fins.

According to an embodiment of the present invention, each of the edges may have a serrated shape or a wavy shape.

According to an embodiment of the present invention, the heat-dissipating module further comprises a heat-conducting element thermally coupled to the heat-generating element. The first end of the heat pipe is thermally coupled to the heat-conducting element.

According to an embodiment of the present invention, the heat-dissipating module further comprises a casing having an accommodating space and an outlet. The fan is disposed in the accommodating space, the outlet corresponds to the folded surface, and the air current passes through the outlet.

According to an embodiment of the present invention, the second end of the heat pipe may pass through the fins.

Since the edge of each fin are located on the folded surface, the air current may smoothly pass through the folded surface and then pass by the fins as the heat-dissipating module of the present invention operates. Therefore, when the heat-dissipating module of the present invention operates, turbulence occurring at the folded surface may be reduced, such that the noise resulted from the turbulence may be reduced.

In order to make the aforementioned and other features and advantages of the present invention more comprehensible, embodiments accompanied with figures are described in detail below.

### BRIEF DESCRIPTION OF THE DRAWINGS

FIG. 1A is a three-dimensional exploded view of a conventional heat-dissipating module.

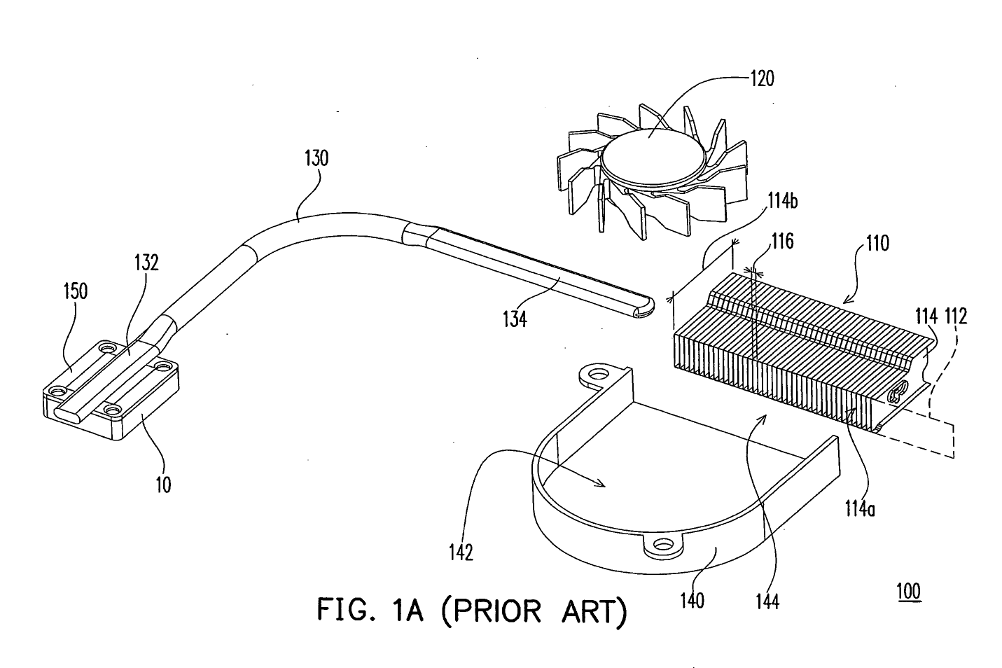

FIG. 1B is a three-dimensional assembled view of the heat-dissipating module of FIG. 1A.

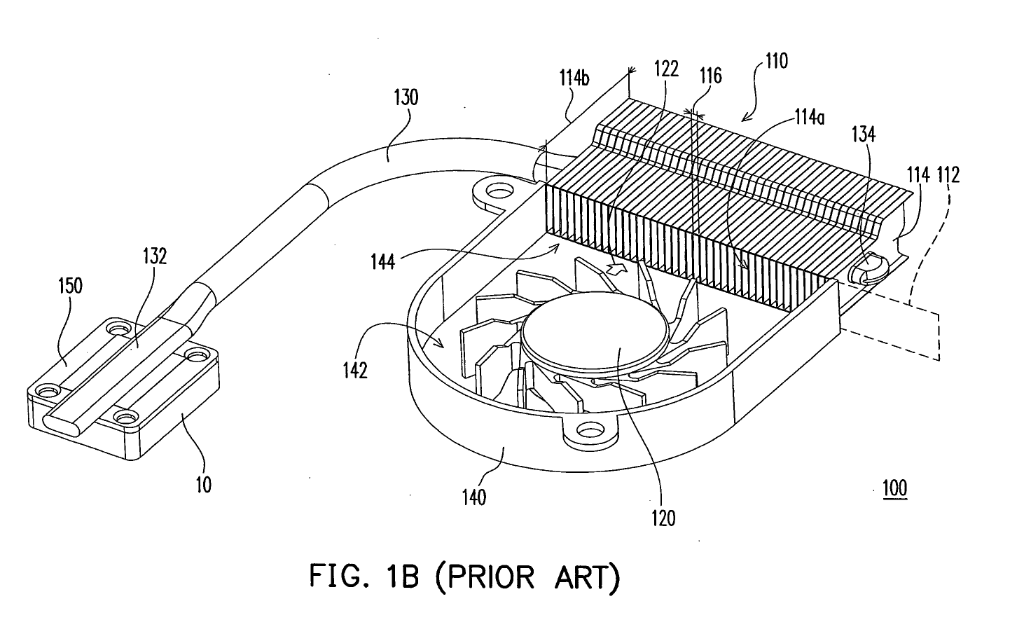

FIG. 2A is a three-dimensional exploded view of a heat-dissipating module in accordance with an embodiment of the present invention.

FIG. 2B is a three-dimensional assembled view of the heat-dissipating module of FIG. 2A.

### DESCRIPTION OF THE EMBODIMENTS

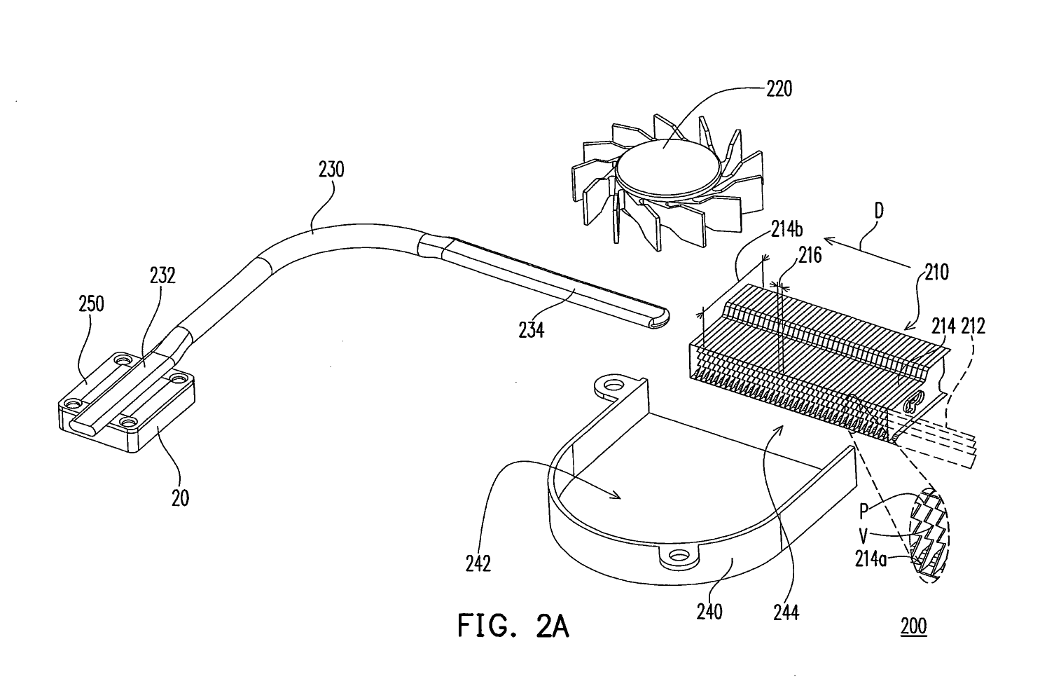

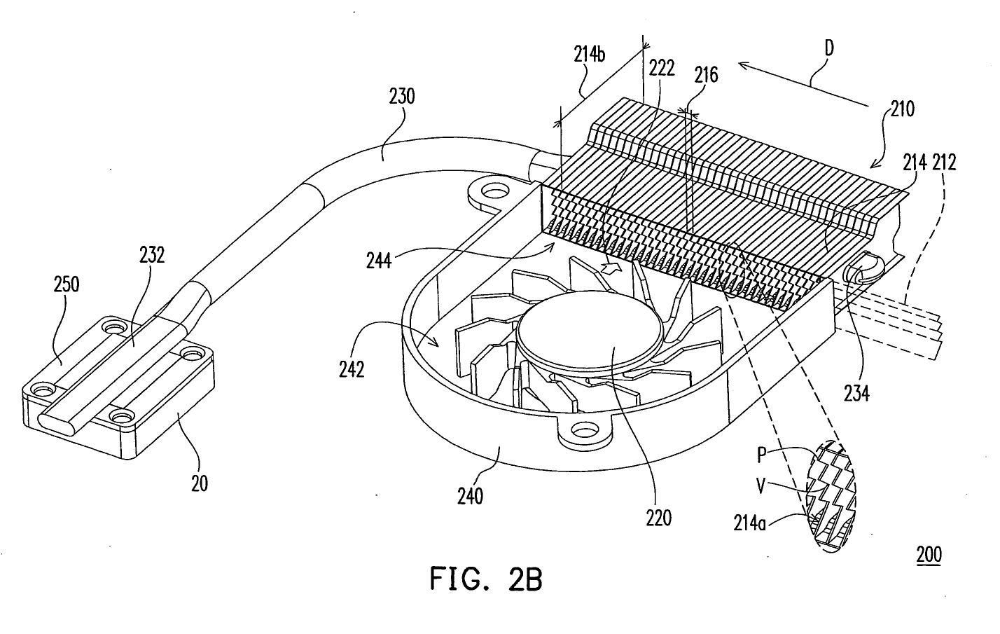

FIG. 2A is a three-dimensional exploded view of a heat-dissipating module in accordance with an embodiment of the present invention, and FIG. 2B is a three-dimensional assembled view of the heat-dissipating module of FIG. 2A. It should be noted that, for the convenience of illustration, a folded surface 212 of FIGS. 2A and 2B is shown to extend beyond the fin module 210 to clearly show the shape of the folded surface 212.

Referring to FIGS. 2A and 2B, the heat-dissipating module 200 is adapted for cooling a heat-generating element 20. The heat-dissipating module 200 includes a fin module 210, a fan 220 and a heat pipe 230. The fin module 210 includes a plurality of fins 214. Each fin 214 has an edge 214a facing the fan 220, and the edges 214a are located on a folded surface (i.e. corrugated surface) 212. In other words, each edge 214a includes at least one peak P (FIGS. 2A and 2B each illustrate multiple peaks P) and at least one valley V (FIGS. 2A and 2B each illustrate multiple valleys V).

The fan 220 may be disposed adjacent to the folded surface 212 and is adapted for generating an air current 222. The air current 222 passes through the folded surface 212 and then passes by the fins 214. In the present embodiment, the air current 222 flows into a plurality clearances 216 and each clearance 216 is formed between corresponding adjacent fins 214. As the air current 222 passes through the folded surface 212, the air current 222 first passes through the peaks P of each edge 214a and then through the valleys V of each edge 214a. In addition, the heat pipe 230 includes a first end 232 and a second end 234. The first end 232 is thermally coupled to the heat-generating element 20, and the second end 234 may pass through the fins 214 to be thermally coupled to the fins 214.

The development of electronic devices (e.g., computers) toward miniaturization results in the room being smaller and smaller for the heat-dissipating module 200, and the designer requires that a minimum distance between the fan 220 and the folded surface 212 is kept to be larger than a predetermined value. Because the edge 214a of each of the fins 214 is located on the folded surface 212, the air current 222 may smoothly pass through the folded surface 212 and into the clearances 216 during operation of the heat-dissipating module 200.

In other words, as the air current 222 passes through the folded surface 212, the air current 222 first passes by the peaks P of each edge 214a and then passes by the valleys V of each edge 214a. Therefore, when the heat-dissipating module 200 of the present embodiment operates, turbulence occurring at the folded surface 212 may be reduced, such that the noise resulted from the turbulence may be reduced.

In addition, unlike the conventional heat-dissipating module, it is unnecessary to reduce the size of the fan 220 of the heat-dissipating module 200 of the present embodiment and to completely reduce the length 214b of each fin 214 of the heat-dissipating module 200 of the present embodiment and, therefore, the heat-dissipating capacity of the heat-dissipating module 200 of the present embodiment may be good.

In the present embodiment, the fins 214 are arranged in a direction D and the direction D is perpendicular to the maximum heat-dissipating surface of each fin 214. When viewed from the direction D, each edge 214a may have a serrated shape. However, each edge 214a may have a wavy shape (not shown), according to various requirements. Therefore, the present embodiment is merely an example and is not intended to limit the present invention.

In the present embodiment, the heat-dissipating module 200 further includes a casing 240 and a heat-conducting element 250. The casing 240 has an accommodating space 242 and an outlet 244. The fan 220 is disposed in the accommodating space 242, the outlet 244 corresponds to the folded surface 212, and the air current 222 passes through the outlet 244. The heat-conducting element 250 is thermally coupled to the heat-generating element 20, and the first end 232 of the heat pipe 230 is thermally coupled to the heat-conducting element 250.

In sum, the heat-dissipating module of the present invention has at least the following advantages:

1. Since the edge of each fin are located on the folded surface, the air current may smoothly pass through the folded surface and into the clearances and then pass by the fins as the heat-dissipating module of the present invention operates. In other words, as the air current passes through the folded surface, the air current first passes by the peaks of each edge, and then passes by the valleys of each edge. Therefore, when the heat-dissipating module of the present invention operates, turbulence occurring at the folded surface is reduced, such that the noise caused by the turbulence is reduced.

2. Unlike the conventional heat-dissipating module, it is unnecessary to reduce the size of the fan of the heat-dissipating module of the present invention and to completely reduce the length of each fin of the heat-dissipating module of the present invention and, therefore, the heat-dissipating capacity of the heat-dissipating module of the present invention may be good.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat-dissipating module adapted for cooling a heat-generating element, comprising:
a fan adapted for generating an air current;
a plurality of fins, wherein each of the fins has an edge facing the fan, the edges are located on a folded surface, and the air current first passes through the folded surface and then passes by the fins; and
a heat pipe, wherein a first end of the heat pipe is thermally coupled to the heat-generating element, and a second end of the heat pipe is thermally coupled to the fins.

2. The heat-dissipating module of claim 1, wherein each of the edges has a serrated shape or a wavy shape.

3. The heat-dissipating module of claim 1, further comprising a heat-conducting element thermally coupled to the heat-generating element, wherein the first end of the heat pipe is thermally coupled to the heat-conducting element.

4. The heat-dissipating module of claim 1, further comprising a casing having an accommodating space and an outlet, wherein the fan is disposed in the accommodating space, the outlet corresponds to the folded surface, and the air current passes through the outlet.

5. The heat-dissipating module of claim 1, wherein the second end of the heat pipe passes through the fins.
